(19) United States
(12) Patent Application Publication
(10) Pub. No.: US 2009/0174039 A1
(43) Pub. Date: Jul. 9, 2009

(54) Semiconductor device and method of forming the same

(75) Inventors: Chan-Mi Lee, Hwaseong-si (KR); Jong-Chul Park, Suwon-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 12/318,774

(22) Filed: Jan. 8, 2009

(30) Foreign Application Priority Data
Jan. 8, 2008 (KR) 10-2008-0002191

(51) Int. Cl. H01L 27/00

(52) U.S. Cl. 257/622; 257/E27.001

(57) ABSTRACT

A semiconductor device and a method of forming the same are provided. A semiconductor device may comprise a semiconductor substrate including a main surface configured to define a groove, a trench, and a cavity sequentially disposed downward from a given region of the main surface and open toward the main surface.

### PRIORITY STATEMENT

This application claims priority under 35 USC § 119 to Korean Patent Application No. 10-2008-0002191, filed on Jan. 8, 2008, with the Korean Intellectual Property Office (KIPO), the entire contents of which are incorporated herein by reference.

### BACKGROUND

1. Field

Example embodiments relate to a semiconductor device and a method of forming the same.

2. Description of Related Art

In recent years, fabrication of semiconductor devices has kept up with research conducted on increasing the channel length of a transistor due to the shrinkage of design rules and reducing the intensity of an electrical field concentrating in a specific portion of a semiconductor substrate during the drive of the transistor. For example, a MOS transistor having a recessed gate electrode and a method of fabricating the same have been disclosed in the related art.

According to the related art, upper and lower trench regions may be disposed in a semiconductor substrate. A gate pattern may fill the upper and lower trench regions. The gate pattern may constitute a transistor along with the semiconductor substrate. The upper trench region may reduce concentration of an electrical field between the gate pattern and the upper trench region during the drive of the transistor. However, the transistor cannot increase a channel length under the gate pattern to overcome a reduction in the design rule.

In another approach, a method of fabricating a semiconductor device having a recessed gate has been proposed in the related art. According to the related art, first and second recesses may be disposed in a semiconductor substrate. A gate pattern may be disposed to fill the first and second recesses. The gate pattern may constitute a semiconductor device along with the semiconductor substrate.

The semiconductor device may increase the channel length of a transistor under the gate pattern using the second recess to overcome a reduction in the design rule. However, because the semiconductor device has a convex surface contacting the gate pattern over the first recess, the concentration of an electrical field cannot be reduced.

### SUMMARY

Example embodiments provide a semiconductor device including a groove, a trench, and a cavity formed in a semiconductor substrate. Example embodiments also provide a method of forming a semiconductor device including a groove, a trench, and a cavity formed in an active region of a semiconductor substrate to improve the electrical properties of the semiconductor device.

According to example embodiments, a semiconductor device may include a semiconductor substrate. The semiconductor substrate may have a main surface. The semiconductor substrate may define a groove, a trench, and a cavity sequentially disposed downward from a given region of the main surface and opened toward the main surface. The groove, the trench, and the cavity may have the same central point. The groove may have a concave shape in the main surface of the semiconductor substrate to have a step difference between the groove and the main surface. The trench may connect the groove and the cavity. The cavity may have a round or oval shape. Also, the radius of curvature of the cavity may be different from or the same as that of the groove.

The groove and the cavity may extend from a sidewall of the trench. An extended length of the cavity may be smaller than or the same as an extended length of the groove with respect to the central point. Contact portions among the main surface, the groove, the trench, and the cavity may have smooth surfaces, respectively. The groove, the trench, and the cavity may be in an active region of the semiconductor substrate.

The semiconductor device may further include a conductive pattern filling the groove, the trench, and the cavity and protruding from the main surface of the semiconductor substrate; and an inserted layer between the conductive pattern and the semiconductor substrate and covering the groove, the trench, and the cavity. The inserted layer may be an insulating layer, and the conductive pattern may be one selected from the group consisting of a gate, a bit line, a plug, and an interconnection. Sidewalls of the conductive pattern may be on one selected from the groove and the main surface.

According to example embodiments, a semiconductor device may include a semiconductor substrate including a main surface configured to define a groove, a trench, and a cavity sequentially disposed downward from the main surface, wherein contact portions of the main surface, the groove, the trench, and the cavity have smooth surfaces.

According to example embodiments, a semiconductor device may include a semiconductor substrate including a main surface configured to define a groove, a trench, and a cavity sequentially disposed downward from the main surface, wherein the cavity has an oval shape.

According to example embodiments, a method of forming a semiconductor device may include sequentially forming a pad layer and a mask layer on a main surface of a semiconductor substrate. The pad layer and the mask layer may be formed to have an opening. A preliminary trench may be formed in the semiconductor substrate through the pad layer and the mask layer. The preliminary trench may correspond to the opening. The semiconductor substrate, the pad layer, and the mask layer may be etched through the opening and the preliminary trench, thereby forming a preliminary groove and a trench under the preliminary groove. The preliminary groove and the trench may be formed to expose the semiconductor substrate.

A spacer layer may be formed on the mask layer to cover the preliminary groove and the trench. The spacer layer may be formed of an oxygen-rich material. The spacer layer may be etched, thereby forming a trench spacer on a sidewall of the trench. The trench spacer may be formed to expose a sidewall of the preliminary groove and a bottom surface of the trench. The semiconductor substrate may be etched using the pad layer, the mask layer, and the trench spacer as an etch mask, thereby forming a groove and a cavity on and under the trench spacer, respectively.

Forming the preliminary groove and the trench may include partially etching the mask layer to increase a diameter of an upper portion of the preliminary trench; and etching the semiconductor substrate and the pad layer using the mask layer as an etch mask. The preliminary groove and the trench may be defined by the semiconductor substrate.

Partially etching the mask layer may include the use of O₂ and CF₄ process gases. The O₂ process gas may have a higher mixture rate than the CF₄ process gas. The pad layer may be an insulating layer formed of silicon oxide. The mask layer may be one selected from an amorphous carbon layer and a photoresist layer.

Etching the semiconductor substrate and the pad layer may include being performed using CF₄ and Ar process gases. The spacer layer may be formed using O₂ and N₂ process gases. The O₂ process gas may have a higher mixture rate than the N₂ process gas. Forming the trench spacer may include anisotropically etching the spacer layer using CF₄ and Ar process gases and using the semiconductor substrate, the pad layer, and the mask layer as an etch buffer layer. Forming the groove and the cavity may include isotropically etching the semiconductor substrate using SF₆, Cl₂, and O₂ process gases. The groove, the trench, and the cavity may be formed in an active region of the semiconductor substrate.

The method may further include removing the pad layer, the mask layer, and the trench spacer from the semiconductor substrate; forming an inserted layer on the semiconductor substrate to cover the groove, the trench, and the cavity; and forming a conductive pattern on the inserted layer to fill the groove, the trench, and the cavity. The inserted layer may be an insulating layer, and the conductive pattern may be one selected from the group consisting of a gate, a bit line, a plug, and an interconnection.

According to example embodiments, a method of forming a semiconductor device may include sequentially forming a pad layer and a mask layer on a main surface of a semiconductor substrate. The pad layer and the mask layer may have an opening. A preliminary groove may be in the semiconductor substrate through the pad layer and the mask layer. The preliminary groove may correspond to the opening. An alignment spacer may be formed on sidewalls of the opening and the preliminary groove. The alignment spacer may be formed to expose a bottom surface of the preliminary groove. The semiconductor substrate may be etched using the mask layer and the alignment spacer as an etch mask, thereby forming a trench, the trench formed under the preliminary groove. A spacer layer may be formed on the mask layer to cover the alignment spacer and the trench. The spacer layer may be formed of an oxygen-rich material. The spacer layer and the alignment spacer may be etched, thereby forming a trench spacer on a sidewall of the trench. The trench spacer may be formed to expose the sidewall of the preliminary groove and a bottom surface of the trench. The semiconductor substrate may be etched using the pad layer, the mask layer, and the trench spacer as an etch mask, thereby forming a groove and a cavity on and under the trench spacer, respectively.

The pad layer may include an insulating layer formed of silicon oxide. The mask layer may comprise an amorphous carbon layer. The alignment spacer may comprise an insulating layer having a different etch rate from the mask layer, the pad layer, and the semiconductor substrate. The preliminary groove and the trench may be defined by the semiconductor substrate.

Forming the spacer layer may include the use of O₂ and N₂ process gases. The O₂ process gas may have a higher mixture rate than the N₂ process gas. Forming the trench spacer may include partially removing the spacer layer using the semiconductor substrate, the mask layer, and the alignment spacer as an etch buffer layer until the bottom surface of the trench is exposed; and removing the alignment spacer from the semiconductor substrate using the semiconductor substrate, the pad layer, the mask layer, and the trench spacer as an etch buffer layer. The spacer layer may be exposed to CF₄ and Ar process gases and etched using an anisotropic etching process. The alignment spacer may be exposed to CHF₃, CH₃F, and O₂ process gases and etched using an isotropic etching process.

Forming the groove and the cavity may include isotropically etching the semiconductor substrate using SF₆, Cl₂, and O₂ process gases. The groove, the trench, and the cavity may be formed in an active region of the semiconductor substrate. The method may further include removing the pad layer, the mask layer, and the trench spacer from the semiconductor substrate; forming an inserted layer on the semiconductor substrate to cover the groove, the trench, and the cavity; and forming a conductive pattern on the inserted layer to fill the groove, the trench, and the cavity. The inserted layer may be an insulating layer, and the conductive pattern may be one selected from the group consisting of a gate, a bit line, a plug, and an interconnection.

### BRIEF DESCRIPTION OF THE DRAWINGS

Example embodiments are described in further detail below with reference to the accompanying drawings. It should be understood that various aspects of the drawings may be exaggerated for clarity.

FIG. 1 is a plan view showing a semiconductor device according to example embodiments;

FIG. 2 is a cross-sectional view showing a semiconductor device taken along line I-I′ of FIG. 1; and

FIGS. 3-11 are cross-sectional views illustrating a method of forming a semiconductor device taken along line I-I′ of FIG. 1.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Various example embodiments will now be described more fully with reference to the accompanying drawings in which some example embodiments are shown. Example embodiments may, however, be embodied in many different forms and should not be construed as limited to the example embodiments set forth herein. Rather, these example embodiments are provided so that this disclosure will be thorough and complete, and will fully convey the scope of example embodiments to those skilled in the art. In the drawings, the thicknesses of layers and regions may be exaggerated for clarity.

It will be understood that when an element or layer is referred to as being “on,” “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, e.g., “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms including technical and scientific terms used herein have the same meaning as commonly understood by one of ordinary skill in the art to which example embodiments belongs. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

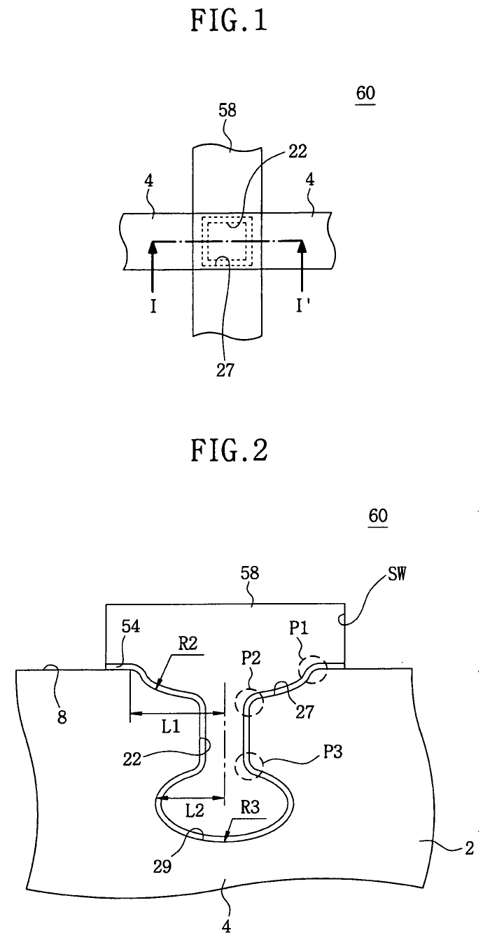

FIG. 1 is a plan view showing a semiconductor device according to example embodiments, and FIG. 2 is a cross-sectional view showing a semiconductor device taken along line I-I′ of FIG. 1. Referring to FIGS. 1 and 2, a semiconductor device 60 according to example embodiments may include a semiconductor substrate 2. The semiconductor substrate 2 may comprise single crystalline silicon. The semiconductor substrate 2 may have an N-type or P-type conductivity. The semiconductor substrate 2 may have an active region 4 as shown in FIGS. 1 and 2. The semiconductor substrate 2 may have a main surface 8 as shown in FIG. 2.

According to the example embodiments, a groove 27 may be disposed in a predetermined or given region of the main surface 8 of the semiconductor substrate 2 as shown in FIG. 2. A sidewall of the groove 27 may be in contact with the main surface 8 of the semiconductor substrate 2. The groove 27 may extend from the main surface 8 of the semiconductor substrate 2 toward a bottom surface of the semiconductor substrate 2. The groove 27 may have a concave shape to have a step difference between the groove 27 and the main surface 8. The groove 27 may be disposed adjacent to the main surface 8 of the semiconductor substrate 2. A trench 22 may be disposed under the groove 27.

According to example embodiments, the trench 22 may have the same central point as the groove 27 and extend from the groove 27 toward the bottom surface of the semiconductor substrate 2 as shown in FIG. 2. The trench 22 and the groove 27 may be opened toward the main surface 8 of the semiconductor substrate 2. A cavity 29 may be disposed under the trench 22. The cavity 29 may be opened toward the main surface 8 of the semiconductor substrate 2 through the trench 22 and the groove 29. The trench 22 may have a vertical sidewall and connect the groove 27 and the cavity 29.

According to example embodiments, the cavity 29 may be disposed to have the same central point as the trench 22 and the groove 27 as shown in FIG. 2. As a result, the semiconductor substrate 2 may define the trench 22, the groove 27, and the cavity 29. The cavity 29 may have a round shape, e.g., an oval shape. A radius of curvature R3 of the cavity 29 may be different from a radius of curvature R2 of the groove 27. The radius of curvature R3 of the cavity 29 may be equal to the radius of curvature R2 of the groove 27. The cavity 29 may extend from the sidewall of the trench 22 along with the groove 27.

According to example embodiments, an extended length L2 of the cavity 29 may be different from or smaller than an extended length L1 of the groove 27 with respect to the same central point as shown in FIG. 2. The extended length L2 of the cavity 29 may be equal to the extended length L1 of the groove 27 with respect to the same central point. The main surface 8, the trench 22, the groove 27, and the cavity 29 may have contact portions P1, P2, and P3, which may have smooth surfaces, respectively, as shown in FIG. 2. The trench 22, the groove 27, and the cavity 29 may be disposed in the active region 4 of the semiconductor substrate 2 as shown in FIGS. 1 and/or 2.

According to example embodiments, the semiconductor device 60 may further include an inserted layer 54 and a conductive pattern 58 as shown in FIGS. 1 and/or 2. The inserted layer 54 may be interposed between the semiconductor substrate 2 and the conductive pattern 58 and cover the trench 22, the groove 27, and the cavity 29 as shown in FIG. 2. The inserted layer 54 may comprise an insulating layer having one selected from a lower dielectric constant than that of silicon nitride or a higher dielectric constant than that of silicon nitride. The inserted layer 54 may comprise at least two insulating layers that are stacked sequentially. The conductive pattern 58 may be disposed on the inserted layer 54 to fill the trench 22, the groove 27, and the cavity 29 and protrude from the main surface 8 of the semiconductor substrate 2.

According to example embodiments, the conductive pattern 58 may comprise one selected from the group consisting of a gate, a bit line, and a metal interconnection. The conductive pattern 58 may be a plug that fills the trench 22, the groove 27, and the cavity 29 and may or may not protrude from the main surface 8 of the semiconductor substrate 2. Sidewalls SW of the conductive pattern 58 may be disposed on one selected from the main surface 8 and the groove 27. When the conductive pattern 58 is a gate, a transistor may be provided to the semiconductor device 60 along with the semiconductor substrate 2 and the inserted layer 54. The groove 27 formed in the semiconductor substrate 2 may reduce the intensity of an electrical field concentrating in an upper portion of the trench 22 under the conductive pattern 58. The cavity 29 formed in the semiconductor substrate 2 may increase the channel length of the transistor.

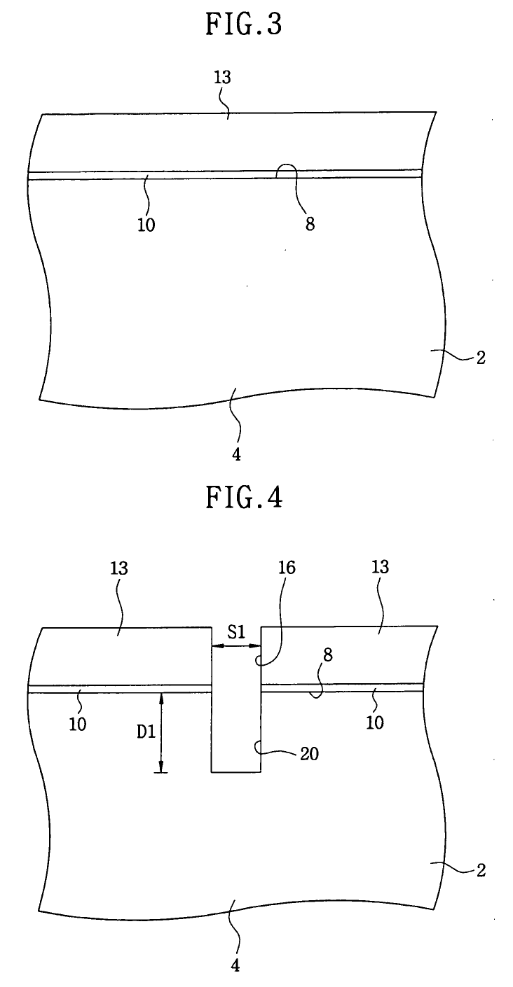

Hereinafter, a method of forming a semiconductor device according to example embodiments will now be described with reference to FIGS. 3-11. FIGS. 3-6 are cross-sectional views illustrating a method of forming a semiconductor device taken along line I-I′ of FIG. 1, according to example embodiments. Referring to FIG. 3, a semiconductor substrate 2 may be prepared according to example embodiments. The semiconductor substrate 2 may comprise single crystalline silicon. The semiconductor substrate 2 may have an N-type or P-type conductivity type. The semiconductor substrate 2 may have a main surface 8. The semiconductor substrate 2 may have an active region 4. A pad layer 10 and a mask layer 13 may be sequentially formed on the main surface 8 of the semiconductor substrate 2. The pad layer 10 may be an insulating layer, which may comprise silicon oxide. Also, the mask layer 13 may be one selected from an amorphous carbon material and a photoresist material.

Referring to FIG. 4, a photoresist layer (not shown) may be formed on the mask layer 13 according to example embodiments. The photoresist layer may be formed to have a through portion. The mask layer 13 and the pad layer 10 may be sequentially etched through the through portion using the photoresist layer as an etch mask. As a result, the pad layer 10 and the mask layer 13 may have a first opening 16 exposing the main surface 8 of the semiconductor substrate 2. The first opening 16 may be formed to have a predetermined or given diameter S1.

According to example embodiments, after the first opening 16 is formed, the photoresist layer may be removed from the semiconductor substrate 2. The semiconductor substrate 2 may be etched using the pad layer 10 and the mask layer 13 as an etch mask, thereby forming a preliminary trench 20. The preliminary trench 20 may be formed to have the same diameter as the first opening 16 and extend from the main surface 8 of the semiconductor substrate 2 to a predetermined or given depth D1.

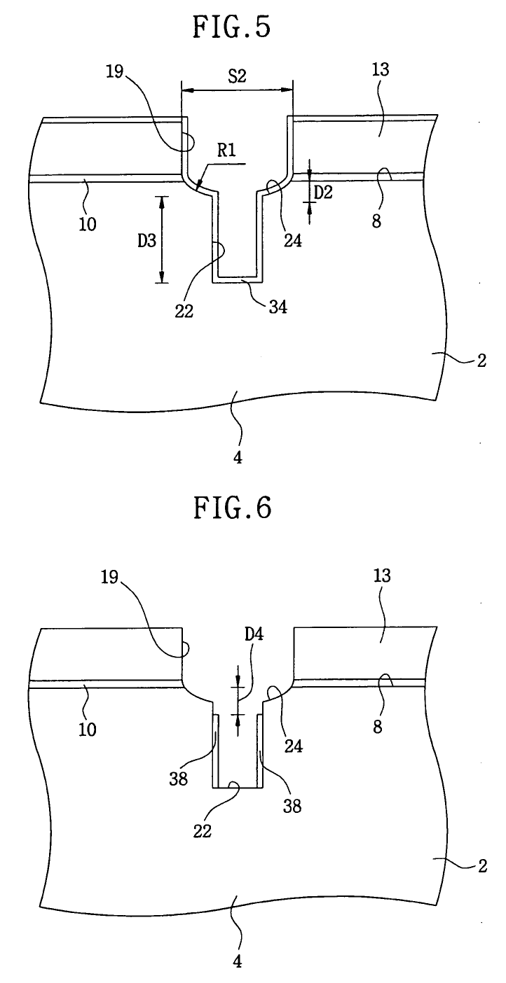

Referring to FIG. 5, according to example embodiments, the mask layer 13 may be partially etched through the preliminary trench 20, thereby increasing the diameter of an upper portion of the preliminary trench 20. Partially etching the mask layer 13 may comprise being performed using O₂ and CF₄ process gases. The O₂ process gas may have a higher mixture rate than the CF₄ process gas. In example embodiments, the pad layer 10 and the mask layer 13 may have a second opening 19 exposing the main surface 8 of the semiconductor substrate 2. After that, the semiconductor substrate 2 and the pad layer 10 may be etched through the second opening 19 using the mask layer 13 as an etch mask. Etching the semiconductor substrate 2 and the pad layer 10 may be performed using CF₄ and Ar process gases. After the semiconductor substrate 2 and the pad layer 10 are etched, a preliminary groove 24 may be formed under the pad layer 10. The preliminary groove 24 may extend from the main surface 8 of the semiconductor substrate 2 toward a bottom surface of the semiconductor substrate 2 to a predetermined or given depth D2.

According to example embodiments, the preliminary groove 24 may be formed to have the same diameter S2 as the second opening 19. The preliminary groove 24 may be formed to have a predetermined or given radius of curvature R1. Also, a trench 22 may be formed under the preliminary groove 24 and defined by the semiconductor substrate 2. The trench 22 may be formed to have a smaller diameter than the preliminary groove 24. The trench 22 may extend toward a bottom surface of the preliminary groove 24 to a predetermined or given depth D3.

According to example embodiments, after the trench 22 and the preliminary groove 24 are formed, a spacer layer 34 may be formed on the mask layer 13 to cover the trench 22 and the preliminary groove 24. The spacer layer 34 may be formed in-situ using a semiconductor etching apparatus for forming the trench 22 and the preliminary groove 24 or formed ex-situ using a different semiconductor etching apparatus from the semiconductor etching apparatus. Forming the spacer layer 34 may include the use of O₂ and N₂ process gases. The O₂ process gas may have a higher mixture rate than the N₂ process gas. Alternatively, each of the semiconductor etching apparatuses may employ only an O₂ process gas. As a result, the spacer layer 34 may be formed of an oxygen-rich material.

Referring to FIG. 6, according to example embodiments, the spacer layer 34 may be anisotropically etched using the semiconductor substrate 2, the pad layer 10, and the mask layer 13 as an etch buffer layer. Thus, a trench spacer 38 may be formed on a sidewall of the trench 22. The trench spacer 38 may be formed to expose a sidewall of the preliminary groove 24 and a bottom surface of the trench 22. Forming the trench spacer 38 may comprise etching the spacer layer 34 using CF₄ and Ar process gases and using the semiconductor substrate 2, the pad layer 10, and the mask layer 13 as an etch buffer layer. The trench spacer 38 may extend from the main surface 8 of the semiconductor substrate 2 toward the bottom surface of the semiconductor substrate 2 to a predetermined or given depth D4.

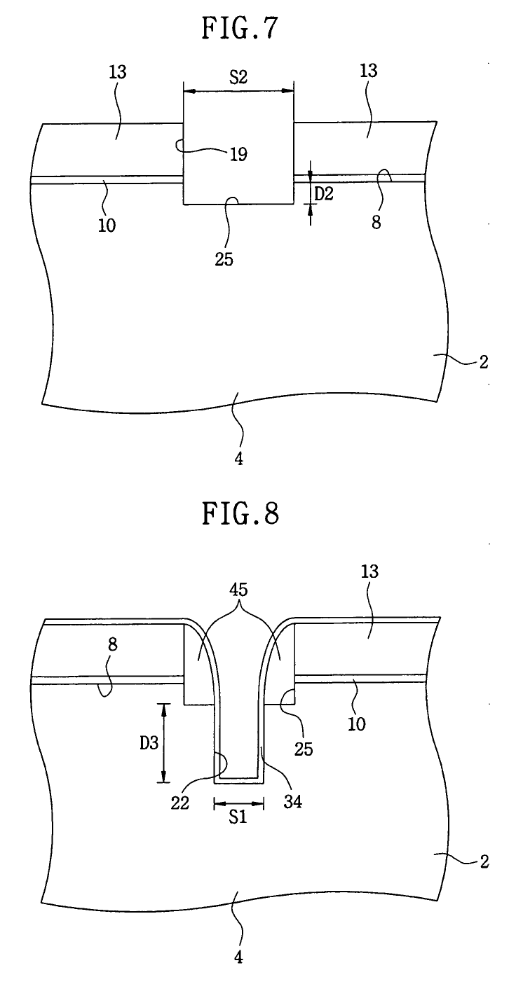

FIGS. 7-9 are cross-sectional views illustrating a method of forming a semiconductor device taken along line I-I′ of FIG. 1, according to example embodiments. Also, example embodiments may include manufacturing a structure having a semiconductor substrate 2, a pad layer 10 and a mask layer 13 which are sequentially stacked.

Referring to FIG. 7, the pad layer 10 may be an insulating layer formed of silicon oxide according to example embodiments. The mask layer 13 may be an amorphous carbon material. A photoresist layer (not shown) may be formed on the mask layer 13. The photoresist layer may be formed to have a through portion. The mask layer 13 and the pad layer 10 may be sequentially etched through the through portion using the photoresist layer as an etch mask. As a result, the pad layer 10 and the mask layer 13 may have a second opening 19 exposing a main surface 8 of the semiconductor substrate 2. The second opening 19 may be formed to have a predetermined or given diameter S2.

According to example embodiments, after the second opening 19 is formed, the photoresist layer may be removed from the semiconductor substrate 2. The semiconductor substrate 2 may be etched using the pad layer 10 and the mask layer 13 as an etch mask, thereby forming a preliminary groove 25. The preliminary groove 25 may be defined by the semiconductor substrate 2. The preliminary groove 25 may be formed to have the same diameter S2 as the second opening 19 and extend from the main surface 8 of the semiconductor substrate 2 to a predetermined or given depth D2.

Referring to FIG. 8, an alignment spacer 45 may be formed on sidewalls of the second opening 19 and the preliminary groove 25 according to example embodiments. The alignment spacer 45 may comprise an insulating layer having a different etch rate from the semiconductor substrate 2, the pad layer 10, and the mask layer 13. The alignment spacer 45 may be formed of silicon nitride. In example embodiments, the alignment spacer 45 may be formed to expose a bottom surface of the preliminary groove 25. After that, the semiconductor substrate 2 may be etched using the mask layer 13 and the alignment spacer 45 as an etch mask, thereby forming a trench 22. The trench 22 may extend from the bottom surface of the preliminary groove 25 to a predetermined or given depth D3 and has a predetermined or given diameter S1.

According to example embodiments, a spacer layer 34 may be formed on the mask layer 13 to cover the trench 22 and the alignment spacer 45. The spacer layer 34 may be formed in-situ using a semiconductor etching apparatus used for the trench 22 or formed ex-situ using a different semiconductor etching apparatus from the semiconductor etching apparatus. The spacer layer 34 may be formed using O₂ and N₂ process gases. The O₂ process gas may have a higher mixture rate than the N₂ process gas. Alternatively, each of the semiconductor etching apparatuses may employ only an O₂ process gas. As a result, the spacer layer 34 may be formed of an oxygen-rich material.

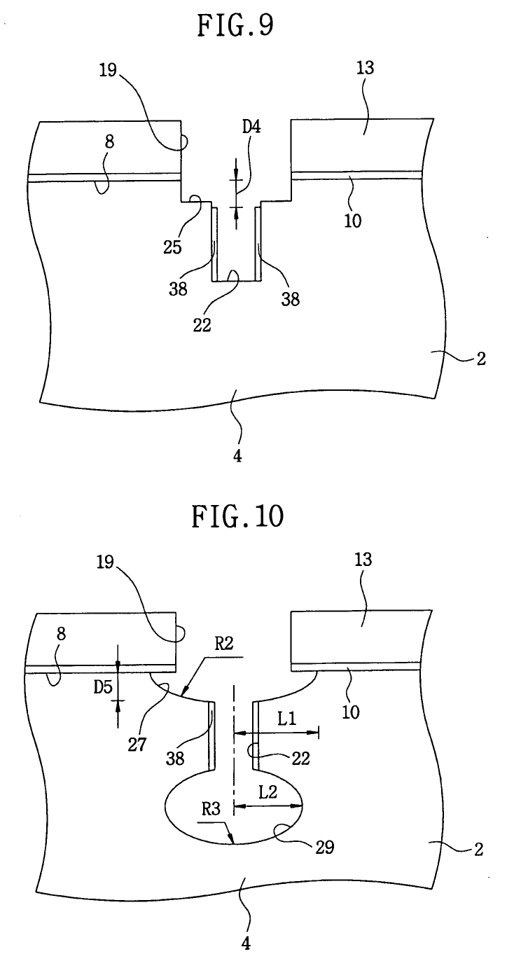

Referring to FIG. 9, the spacer layer 34 may be partially removed using the semiconductor substrate 2, the mask layer 13, and the alignment spacer 45 as an etch buffer layer until a bottom surface of the trench 22 is exposed. In example embodiments, the spacer layer 34 may be exposed to CF₄ and Ar process gases and etched using an anisotropic etching process. Thus, a trench spacer 38 may be formed on a sidewall of the trench 22. Subsequently, the alignment spacer 45 may be removed from the semiconductor substrate 2 using the semiconductor substrate 2, the pad layer 10, the mask layer 13, and the trench spacer 38 as an etch buffer layer. The alignment spacer 45 may be exposed to CHF₃, CH₃F, and O₂ process gases and etched and removed using an isotropic etching process. As a result, the trench spacer 38 may extend from the main surface 8 of the semiconductor substrate 2 toward a bottom surface of the semiconductor substrate 2 to form under a predetermined or given depth D4. The trench spacer 38 may be formed to expose a sidewall of the preliminary groove 25 and the bottom surface of the trench 22.

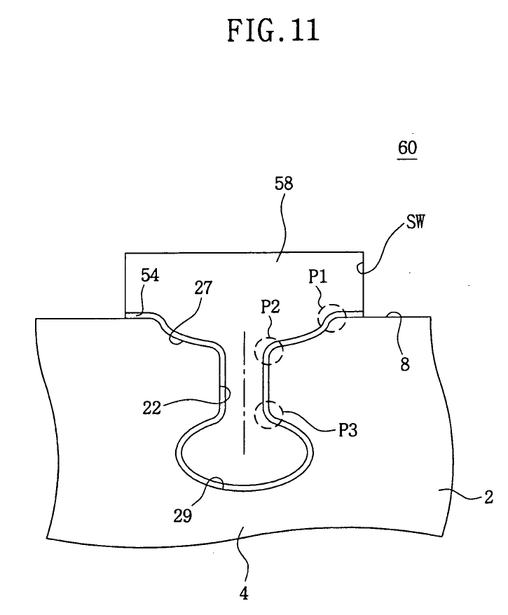

FIGS. 10-11 are cross-sectional views illustrating a method of forming a semiconductor device taken along line I-I′ of FIG. 1, according to example embodiments. Referring to FIG. 10, the semiconductor substrate 2 may be etched using the pad layer 10, the mask layer 13, and the trench spacer 38 as an etch mask according to example embodiments. As a result, a groove 27 and a cavity 29 may be formed on and under the trench spacer 38, respectively. Forming the groove 27 and the cavity 29 may comprise isotropically etching the semiconductor substrate 2 using SF₆, Cl₂, and O₂ process gases. In example embodiments, the trench 22, the groove 27, and the cavity 29 may be formed to have the same central point. The groove 27 may extend from the main surface 8 of the semiconductor substrate 2 toward the bottom surface of the semiconductor substrate 2 to a predetermined or given depth D5.

According to example embodiments, the groove 27 and the cavity 29 may extend from the sidewall of the trench 22 to the same extended length L1 or L2 or different extended lengths L1 and L2 with respect to the same central point. The groove 27 and the cavity 29 may have radii of curvature R2 and R3, respectively. The radius of curvature R2 of the groove 27 may be equal to or different from the radius of curvature R1 of the preliminary groove 24 or 25. Also, the radius of curvature R3 of the cavity 29 may be equal to or different from the radius of curvature R2 of the groove 27.

Referring to FIG. 11, the pad layer 10, the mask layer 13, and the trench spacer 38 may be removed from the semiconductor substrate 2 according to example embodiments. The main surface 8, the trench 22, the groove 27, and the cavity 29 may have contact portions P1, P2, and P3, which may have smooth surfaces, respectively, as shown in FIG. 11. The semiconductor substrate 2 may have smooth surfaces at portions where the main surface 8, the trench 22, the groove 27, and the cavity 29 contact one another. An inserted layer 54 may be formed on the semiconductor substrate 2 to cover the trench 22, the groove 27, and the cavity 29. The inserted layer 54 may comprise an insulating layer having one selected from a lower dielectric constant than silicon nitride and a higher dielectric constant than silicon nitride. The inserted layer 54 may include at least two insulating layers that are stacked sequentially. A conductive pattern 58 may be formed on the inserted layer 54 to fill the trench 22, the groove 27, and the cavity 29.

A sidewall SW of the conductive pattern 58 may be formed on the main surface 8 or the groove 27 according to example embodiments. The conductive pattern 58 may be one selected from the group consisting of a gate, a bit line, a plug, and an interconnection. When the conductive pattern 58 is a gate, the conductive pattern 58 may include a transistor along with the semiconductor substrate 2 and the inserted layer 54. As a result, the transistor may be formed at least one in a semiconductor device 60 of FIG. 1. Because the groove 27 may reduce an electrical field concentrating in the main surface 8 during the drive of the transistor, the electrical characteristics of the semiconductor device 60 may be improved. Also, the cavity 29 may increase the channel length of the transistor. When the conductive pattern 58 is a bit line, a plug, or an interconnection, the conductive pattern 58 may be filled in the trench 22, the groove 27, and the cavity 29 and fixed to the semiconductor substrate 2. As a result, the conductive pattern 58 may be precisely brought into contact with a circuit interconnection during subsequent semiconductor fabrication processes.

As described above, a semiconductor device and a method of forming the same may be provided. The semiconductor device may include a transistor having a conductive pattern that fills a groove, a trench, and a cavity formed in a semiconductor substrate and protrudes from a main surface of the semiconductor substrate. In example embodiments, the conductive pattern may be a gate. The transistor may have the groove that reduces the intensity of an electrical field concentrating in an upper portion of the trench under the conductive pattern. Also, the transistor may include the cavity that increases a channel length under the conductive pattern to overcome the shrinkage of design rules. As a result, despite the shrinkage of the design rules, the semiconductor device may have improved electrical characteristics using the transistor.

Furthermore, the conductive pattern may be a bit line, a metal interconnection, or a plug. When the conductive pattern is a bit line or a metal interconnection, the conductive pattern may be filled in the groove, the trench, and the cavity and fixed to the semiconductor substrate. In example embodiments, because the conductive pattern cannot move in the semiconductor substrate, an electrical short between the conductive pattern and an adjacent bit line or interconnection may not occur. Also, when the conductive pattern is a plug, the conductive pattern may be disposed in the semiconductor substrate to fill the groove, the trench, and the cavity. In example embodiments, because the conductive pattern cannot move in the semiconductor substrate, the conductive pattern may be precisely brought into contact with an upper circuit interconnection. As a result, despite the shrinkage of the design rules, the semiconductor device may have improved interconnection capabilities using the conductive pattern.

While example embodiments have been disclosed herein, it should be understood that other variations may be possible. Such variations are not to be regarded as a departure from the spirit and scope of example embodiments of the present application, and all such modifications as would be obvious to one skilled in the art are intended to be included within the scope of the following claims.

1. A semiconductor device comprising:
a semiconductor substrate including a main surface configured to define a groove, a trench, and a cavity sequentially disposed downward from a given region of the main surface and open toward the main surface.

2. The semiconductor device of claim 1, wherein the groove, the trench, and the cavity have the same central point.

3. The semiconductor device of claim 2, wherein the groove and the cavity extend from a sidewall of the trench.

4. The semiconductor device of claim 3, wherein an extended length of the cavity is smaller than an extended length of the groove with respect to the central point.

5. The semiconductor device of claim 3, wherein an extended length of the cavity is the same as an extended length of the groove with respect to the central point.

6. The semiconductor device of claim 1, wherein the groove has a concave shape in the main surface of the semiconductor substrate to have a step difference between the groove and the main surface.

7. The semiconductor device of claim 1, wherein the trench connects the groove to the cavity.

8. The semiconductor device of claim 1, wherein the cavity has a round shape.

9. The semiconductor device of claim 8, wherein the cavity has an oval shape.

10. The semiconductor device of claim 1, wherein the cavity has a different radius of curvature from the groove.

11. The semiconductor device of claim 1, wherein the cavity has the same radius of curvature as the groove.

12. The semiconductor device of claim 1, wherein contact portions of the main surface, the groove, the trench, and the cavity have smooth surfaces.

13. The semiconductor device of claim 7, wherein the groove, the trench, and the cavity are in an active region of the semiconductor substrate.

14. The semiconductor device of claim 1, further comprising:
a conductive pattern configured to fill the groove, the trench, and the cavity and protrude from the main surface of the semiconductor substrate; and
an inserted layer between the conductive pattern and the semiconductor substrate and configured to cover the groove, the trench, and the cavity.

15. The semiconductor device of claim 14, wherein the inserted layer is an insulating layer.

16. The semiconductor device of claim 14, wherein the conductive pattern is one selected from the group consisting of a gate, a bit line, a plug, and an interconnection.

17. The semiconductor device of claim 1, wherein sidewalls of the conductive pattern are on one selected from the groove and the main surface.

18. A semiconductor device comprising:
a semiconductor substrate including a main surface configured to define a groove, a trench, and a cavity sequentially disposed downward from the main surface,
wherein contact portions of the main surface, the groove, the trench, and the cavity have smooth surfaces.

19. The semiconductor device of claim 18, wherein an extended length of the cavity is equal to or smaller than an extended length of the groove with respect to a same central point.

20. A semiconductor device comprising:
a semiconductor substrate including a main surface configured to define a groove, a trench, and a cavity sequentially disposed downward from the main surface,
wherein the cavity has an oval shape.

21-35. (canceled)
